(19) United States
(12) Patent Application Publication
(10) Pub. No.: US 2016/0349315 A1
(43) Pub. Date: Dec. 1, 2016

(54) MULTILAYER INTERPOSER WITH HIGH BONDING STRENGTH

(71) Applicant: CHUNGHWA PRECISION TEST TECH. CO., LTD., TAOYUAN COUNTY (TW)

(72) Inventors: WEN-TSUNG LEE, NEW TAIPEI CITY (TW); KAI-CHIEH HSIEH, TAOYUAN COUNTY (TW); YUAN-CHIANG TENG, TAOYUAN COUNTY (TW)

(21) Appl. No.: 15/159,031

(22) Filed: May 19, 2016

(30) Foreign Application Priority Data
May 29, 2015 (TW) 104208501

(51) Int. Cl. G01R 31/28; H01L 23/498

(52) U.S. Cl. CPC G01R 31/2884; H01L 23/49822; H01L 23/49838; H01L 23/49827; H01L 23/49811

(57) ABSTRACT

Disclosed is a multilayer interposer with high bonding strength, which is used in wafer testing. The multilayer interposer with high bonding strength comprises a plurality of thin-film layer structures overlapping sequentially. One of the thin-film layer structures comprises at least one first conductive blind via. An interconnection layer electrically connected to the first conductive blind via is configured on the surface of the one of the thin-film layer structures, and the interconnection layer comprises at least one head portion. Another one of the thin-film layer structures comprises at least one second conductive blind via. The bottom of the second conductive blind via contacts both of the corresponding head portion and part of the surface of the one of the thin-film layer structures. Thereby, the bonding strength between layers can be dramatically increased, and the resistance to the thermal shock can be also increased.

### BACKGROUND OF THE INVENTION

1. Field of the Invention

The instant disclosure relates to the field of wafer testing; in particular, to a multilayer interposer with high bonding strength.

2. Description of Related Art

With respect to the process flow in the semiconductor industry, it mainly includes four major steps which are the IC design, the wafer processing, the wafer testing and the wafer packaging. Generally, the step of wafer testing is to test the electric properties of each die of a wafer so as to abandon the defected dies. Specifically, during the wafer testing, the probe head of the probe card pierces to the pad on the die, which forms an electric contact. After that, the testing signals obtained via the probe head will automatically be transmitted to an automatic test equipment (ATE) to continue the following analysis and determination and obtain a test result of the electric properties of each die of a wafer. Thereby, the defected wafer generated during the upstream process will not continually be processed to be a product.

It is hard and costly to manufacture the probe cards, so currently the expensive probe card which includes an interposer and a probe card PCB, wherein the electric contact between the above two is usually formed by the solder ball welding. The cross section of the interposer of the connector is shown in FIG. 1. The interposer of this kind of connector may be damaged because of the following factors: 1) the thermal shock during the solder ball welding; 2) the stress variation during the electroplating process; and 3) the thermal shock during the desoldering and reworking, wherein the thermal shock is the major factor resulting in damage.

With the progress of the semiconductor process, the size of the semiconductor elements has become smaller, and the IC becomes much more delicate, such that it gets harder to do the wafer level measurement.

Usually, increase of the accuracy and the efficiency as the IC operates is required. The tests for wafers, semiconductor components and IC are also essential for lots of processes using new components and exploitations of new materials, especially the wafer level measurement.

There is room and necessity for the improvement regarding to the conventional interposer design, and how to make an improvement with a limited cost is also worth considering.

### SUMMARY OF THE INVENTION

The achievement of the instant disclosure is to provide improved structures of the interface components for wafer testing and the interposer thereof, to get rid of the shortages resulting from the above electric contact made via the solder ball welding method and to improve the conventional operation

To achieve the above goals, the instant disclosure provides a multilayer interposer with high bonding strength, which is used in wafer testing. The multilayer interposer with high bonding strength comprises a core substrate and a thin-film layer structure. The core substrate has a conducting wire on its surface, and the conducting wire has at least one head portion. The thin-film layer structure overlaps the surface of the core substrate, and covers the conducting wire. The thin-film layer structure has at least one conductive blind via, and the bottom of the conductive blind via contacts both of the head portion and part of the surface of the core substrate.

The instant disclosure also provides a multilayer interposer with high bonding strength, which is used in wafer testing. The multilayer interposer with high bonding strength comprises a plurality of thin-film layer structures overlapping sequentially on the core substrate. One of the thin-film layer structures comprises at least one first conductive blind via. An interconnection layer electrically connected to the first conductive blind via is configured on the surface of the one of the thin-film layer structures, and the interconnection layer comprises at least one head portion. Another one of the thin-film layer structures comprises at least one second conductive blind via. The bottom of the second conductive blind via contacts the corresponding head portion and part of the surface of the one of the thin-film layer structures.

To sum up, in the multilayer interposer, the bottom of each conductive blind via contacts both of the corresponding head portion of the conducting wire and part of the surface of the core substrate. Thereby, the overlapping area will increase, and thus the bonding strength between layers can be increased, which further increases the resistance to thermal shock.

For further understanding of the instant disclosure, reference is made to the following detailed description illustrating the embodiments and embodiments of the instant disclosure. The description is only for illustrating the instant disclosure, not for limiting the scope of the claim.

### BRIEF DESCRIPTION OF THE DRAWINGS

Embodiments are illustrated by way of example and not by way of limitation in the figures of the accompanying drawings, in which like references indicate similar elements and in which:

FIG. 1 shows a schematic diagram of a conventional interposer for wafer testing.

FIG. 2 shows a schematic diagram of a multilayer interposer with high bonding strength of the first embodiment of the instant disclosure.

FIG. 3 shows a schematic diagram of the connection relationship among the conductive blind via, the conducting wire and the core substrate in a multilayer interposer with high bonding strength of the first embodiment of the instant disclosure shown in FIG. 2.

FIG. 4 shows another schematic diagram of a multilayer interposer with high bonding strength of the first embodiment of the instant disclosure.

FIG. 5 shows a schematic diagram of the arrangement of the electrical connection pads in a multilayer interposer with high bonding strength of one embodiment of the instant disclosure.

FIG. 6 shows a schematic diagram of the arrangement of the electrical connection pads in a multilayer interposer with high bonding strength of another embodiment of the instant disclosure.

FIG. 7 shows a schematic diagram of a multilayer interposer with high bonding strength of the second embodiment of the instant disclosure.

FIG. 8 shows a schematic diagram of the connection relationship among the conductive blind via, the conducting wire and the core substrate in a multilayer interposer with high bonding strength of the second embodiment of the instant disclosure shown in FIG. 7.

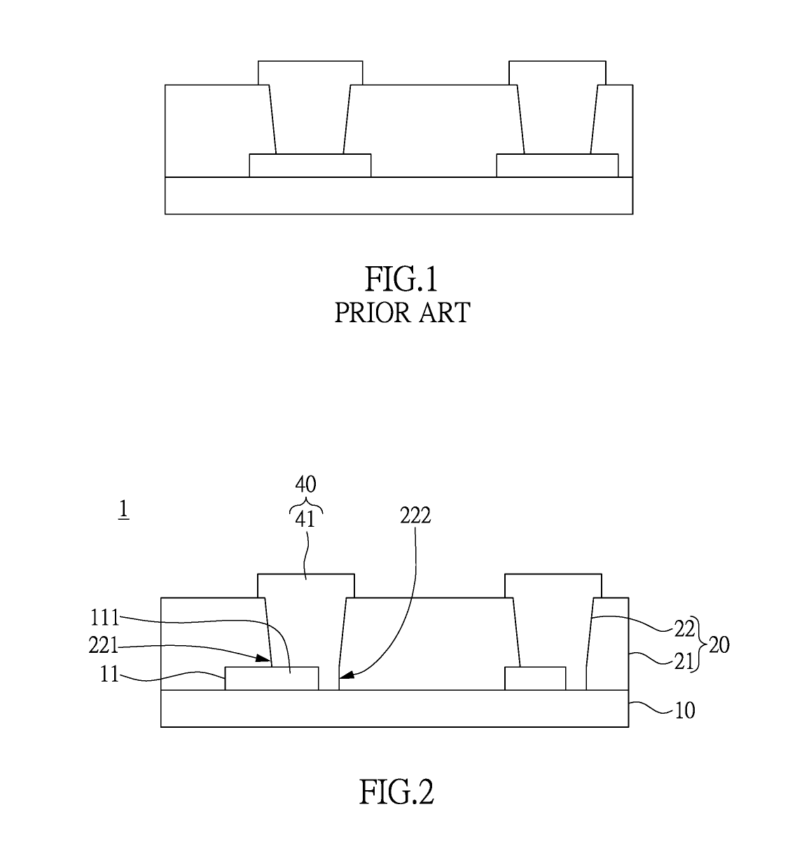

### DETAILED DESCRIPTION OF PREFERRED EMBODIMENTS

The instant disclosure is related to a creative design of the connecting relationship of components in an interposer among the interface components for wafer testing. Compared with the stack-via structure, the instant disclosure has an improved resistance to thermal shock.

The aforementioned illustrations and following detailed descriptions are exemplary for the purpose of further explaining the scope of the instant disclosure. Other objectives and advantages related to the instant disclosure will be illustrated in the subsequent descriptions and appended drawings.

### The First Embodiment

Refer to FIG. 2. FIG. 2 shows a schematic diagram of a multilayer interposer with high bonding strength of the first embodiment of the instant disclosure. This embodiment provides a multilayer interposer with high bonding strength 1, and it comprises a core substrate 10 and a thin-film layer structure 20 overlapping on the core substrate 10.

Within this embodiment, the core substrate 10 can be a doubled-sided core substrate, and preferably, can be a core substrate structured by bounding layers, build-up layers or both of them. The core substrate 10 has an interconnect structure (not shown in FIG. 2). A conducting wire 11 is arranged on the surface of the core substrate 10, and the conducting wire 11 is electrically connected to the interconnect structure of the core substrate 10, wherein the conducting wire 11 has at least one head portion 111. In addition, the interconnect structure can comprise the metal conducting wire (transverse direction), the contact window (the hole on the thin-film), the metal layer (longitudinal via filling plating) and the like. The design of the above element structures can be determined depending on the circuitry.

The thin-film layer structure 20 covers the conducting wire 11, and comprises a thin-film dielectric layer 21 and at least one conductive blind via 22 formed on the thin-film dielectric layer 21. The material of the thin-film dielectric layer 21 can be dry film or wet film, and also the material of the thin-film dielectric layer 21 can be a low-Dk material or a high-Dk material. The conductive blind via 22 can be formed by laser drilling or photolithography process, together with electroplating process or filling conducting material (such as the silver paste). It is worth mentioning that, the bottom of each conductive blind via 22 contacts both the corresponding head portion 111 and part of the surface of the core substrate 10. Thereby, the overlapping area will increase, and thus the bonding strength between layers can be increased, which further increases the resistance to thermal shock.

As shown in FIG. 2, there are two thin-film layer structures 20 in the multilayer interposer 1 and each thin-film layer structure 20 has two conductive blind vias 22, but in other embodiments of the instant disclosure, the amounts of the thin-film layer structure 20 and the conductive blind via 22 can be three or more than three. That is, the above amounts of the thin-film layer structure 20 and the conductive blind via 22 are examples for illustrating but not for restricting the instant disclosure. The amounts of the thin-film layer structure 20 and the conductive blind via 22 can be determined depending on the circuitry design for certain requirement, such as increasing the layout density.

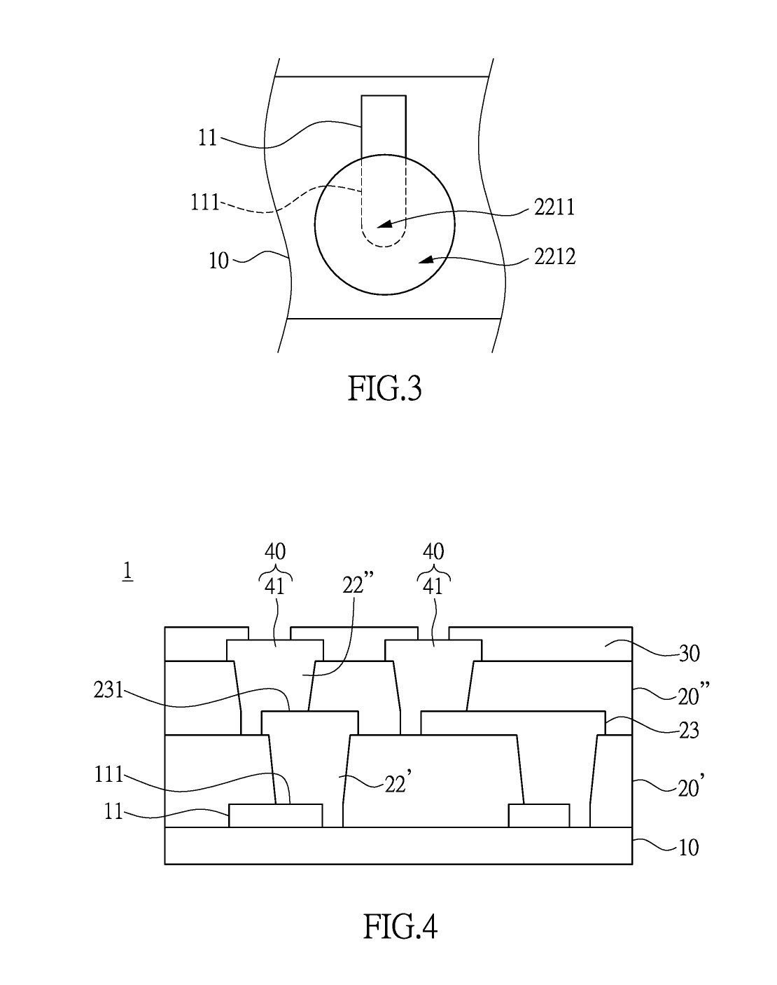

In conjunction with FIG. 2 and FIG. 3, FIG. 2 and FIG. 3 further illustrate the relationship between the conductive blind via 22, the conducting wire 11 and the core substrate 10. The conductive blind via 22 comprises an electrical contact portion 221 and a peripheral contact portion 222 extending from the electrical contact portion 221. The electrical contact portion 221 is mainly configured to connect the corresponding head portion 111, and the peripheral contact portion 222 is configured to connect part of the surface of the core substrate 10.

Specifically, the bottom of the electrical contact portion 221 can be divided into a body region 2211 and a peripheral region 2212, wherein the area and the shape of the body region 2211 correspond to the head portion 111 and the peripheral region 2212 at least surrounds part of the body region 2211. The body region 2211 contacts the top of the head portion 111. Additionally, the peripheral contact portion 222 protrudes from the peripheral region 2212 of the electrical contact portion 221. The peripheral contact portion 222 contacts both of the side surface of the head portion 111 and part of the surface of the core substrate 10.

Refer to FIG. 4. FIG. 4 shows another schematic diagram of a multilayer interposer with high bonding strength of the first embodiment of the instant disclosure. The multilayer interposer 1′ provided by this embodiment comprises a plurality of thin-film layer structures sequentially overlapping on the core substrate 10, such as a first thin-film layer structure 20′ and a second thin-film layer structure 20″. It is worth mentioning that, the conductive blind via 22 can be also applied to the adjacent first thin-film layer structure 20′ and second thin-film layer structure 20″.

In detail, the first thin-film layer structure 20′ has at least one first conductive blind via 22′, and an interconnection layer 23 is arranged on the surface of the first thin-film layer structure 20′, wherein the interconnection layer 23 is electrically connected to the first conductive blind via 22′. The interconnection layer 23 has at least one head portion 231. The second thin-film layer structure 20″ has at least one second conductive blind via 22″ which is unaligned with the corresponding first conductive blind via 22′. The second thin-film layer structure 20″ covers the interconnection layer 23, and the bottom of the second conductive blind via 22″ contacts both of the corresponding head portion 231 and part of the surface of the first thin-film layer structure 20′. Thereby, the multilayer interposer 1 provided by the instant disclosure has a better resistance to thermal shock.

In conjunction with FIGS. 4-6, in the multilayer interposer 1, a solder mask layer 30 and a plurality of electrical connection pads 40 are arranged on the most outer thin-film layer structure (the second thin-film layer structure 20″) to electrically connect the PCB of the test equipment or the wafer on the carrier (not shown) and to proceed with the staged tests during the wafer manufacturing or the final test as the wafer packaging has been finished. The electrical connection pads 40 serving as wafer test points are exposed from the solder mask layer 30, wherein each wafer test point 41 is arranged on and electrically connected to a corresponding conductive blind via 22.

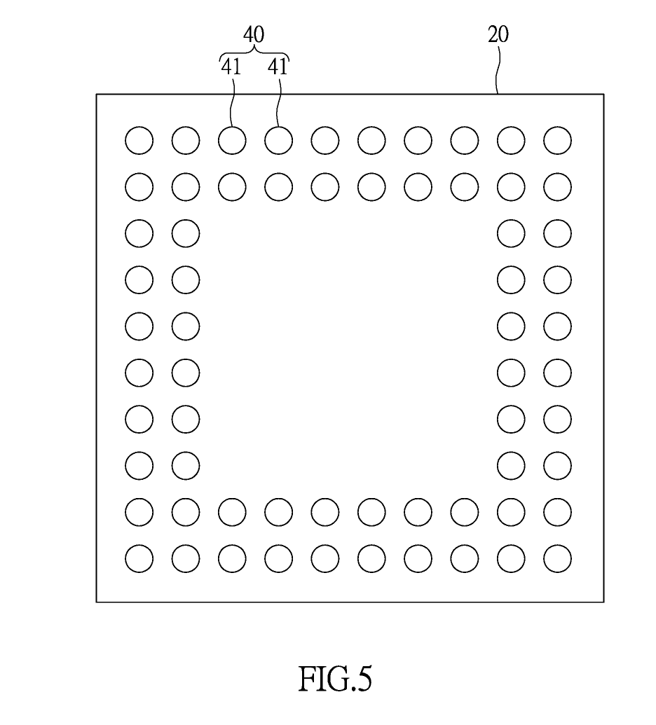

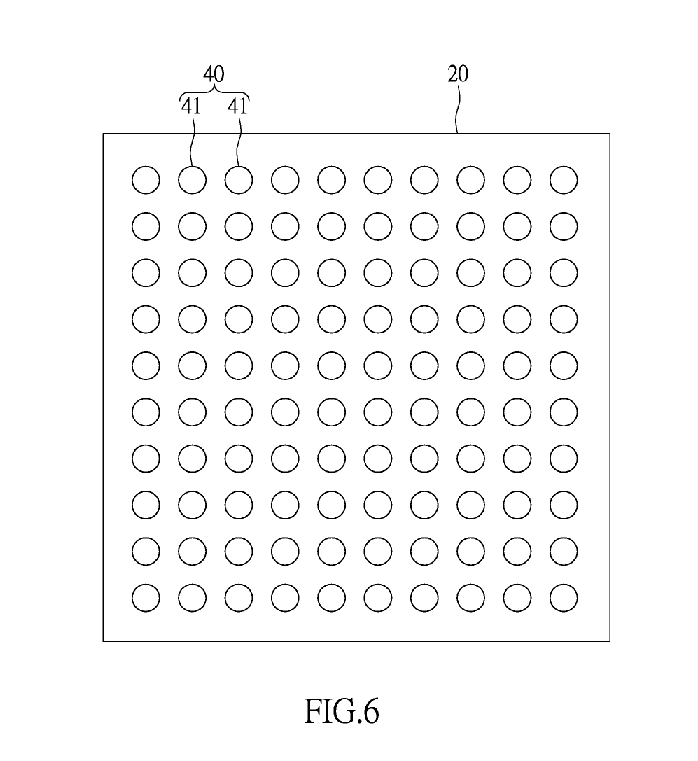

In this embodiment, the electrical connection pads 40 are arranged in a matrix (as shown in FIG. 6) or in a wraparound way (as shown in FIG. 5), and a solder ball can be arranged on each wafer test point as the conductive contact for wafer testing. It should be noted that, the arrangement, the amount, the shape and the size of the electrical connection pads 40 can be determined depending on the circuitry design for certain requirements, such as increasing the layout density, but it is not limited herein.

### The Second Embodiment

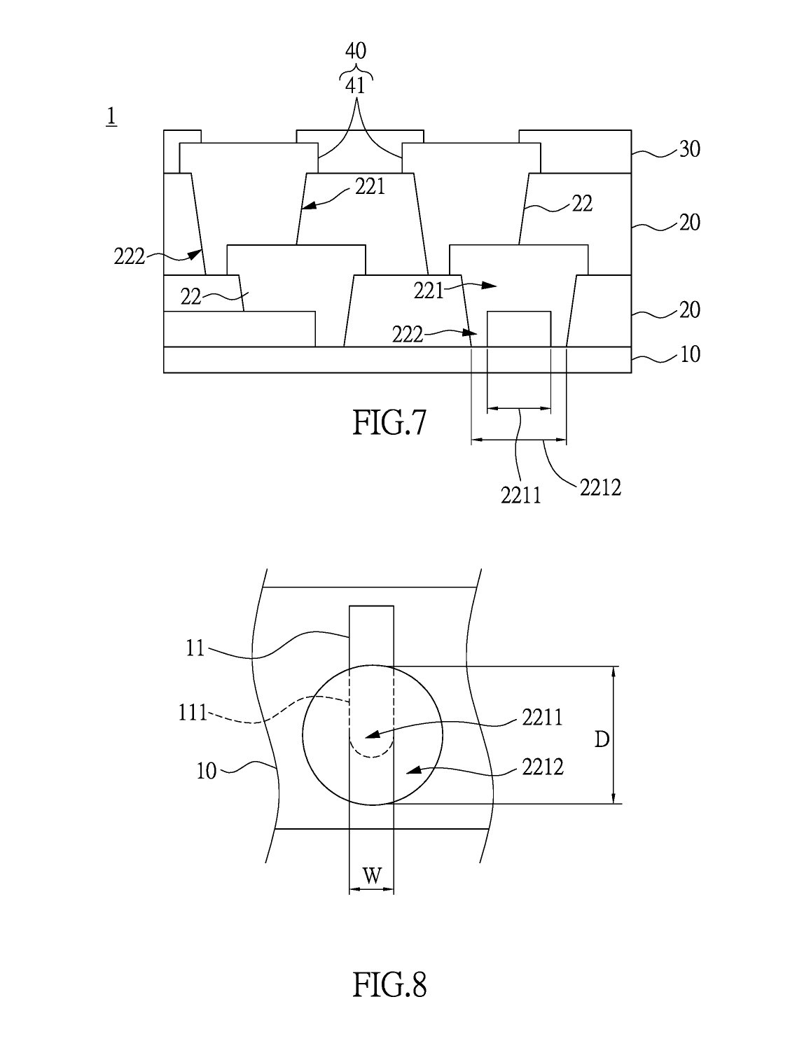

In conjunction with FIG. 7 and FIG. 8, FIG. 7 shows a schematic diagram of a multilayer interposer with high bonding strength of the second embodiment of the instant disclosure, and FIG. 8 shows a schematic diagram of the connection relationship among the conductive blind via, the conducting wire and the core substrate in a multilayer interposer with high bonding strength of the second embodiment of the instant disclosure shown in FIG. 7. The difference between this embodiment and the above embodiment is that, in the thin-film layer structure 20, the diameter D of at least one conductive blind via 22 is larger than the width W of the corresponding head portion 111.

Specifically, the bottom of the electrical contact portion 221 can be divided into a body region 2211 and a peripheral region 2212, wherein the area and the shape of the body region 2211 correspond to the head portion 111 and the peripheral region 2212 entirely surrounds the body region 2211. Accordingly, the side face of the head portion 111 is entirely clad with the peripheral contact portion 222 of the conductive blind via 22, and the peripheral contact portion 222 contacts part of the surface of the core substrate 10.

To sum up, compared with the prior art, in the multilayer interposer of the instant disclosure, the bottom of each conductive blind via contacts both of the corresponding head portion of the conducting wire and part of the surface of the core substrate. Thereby, the overlapping area will increase, and thus the bonding strength between layers can be increased, which further increases the resistance to thermal shock.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A multilayer interposer with high bonding strength, used in wafer testing, comprising:
a core substrate, having a conducting wire on its surface, the conducting wire having at least one head portion; and
a thin-film layer structure, overlapping the surface of the core substrate and covering the conducting wire, the thin-film layer structure having at least one conductive blind via, the bottom of the conductive blind via contacting the head portion and part of the surface of the core substrate.

2. The multilayer interposer with high bonding strength according to claim 1, wherein the conductive blind via comprises an electrical contact portion and a peripheral contact portion extending from the electrical contact portion, the electrical contact portion and the head portion are in mutual contact, and the peripheral contact portion and part of the surface of the thin-film layer structure are in mutual contact.

3. The multilayer interposer with high bonding strength according to claim 2, wherein the electrical contact portion of the conductive blind via comprises a body region and a peripheral region, the body region corresponds to the head portion, the peripheral region surrounds part of the body region, and the peripheral contact portion is formed by extending the peripheral region.

4. The multilayer interposer with high bonding strength according to claim 3, wherein the peripheral region totally surrounds the body region.

5. The multilayer interposer with high bonding strength according to claim 1, wherein an electrical connection pad is configured on the thin-film layer structure.

6. The multilayer interposer with high bonding strength according to claim 5, wherein a plurality of wafer test points extending from the electrical connection pads are arranged in an matrix or in a wraparound way.

7. A multilayer interposer with high bonding strength, used in wafer testing, comprising a plurality of thin-film layer structures overlapping sequentially, wherein one of the thin-film layer structures comprises at least one first conductive blind via, an interconnection layer electrically connected to the first conductive blind via is configured on the surface of the one of the thin-film layer structures, and the interconnection layer comprises at least one head portion, and wherein another one of the thin-film layer structures comprises at least one second conductive blind via, and the bottom of the second conductive blind via contacts the corresponding head portion and part of the surface of the one of the thin-film layer structures.

8. The multilayer interposer with high bonding strength according to claim 7, wherein the first conductive blind via and the second conductive blind via respectively comprise an electrical contact portion and a peripheral contact portion extending from the electrical contact portion, the electrical contact portion is configured to contact the corresponding head portion, and the peripheral contact portion is configured to contact part of the surface of the thin-film layer structure.

9. The multilayer interposer with high bonding strength according to claim 8, wherein the electrical contact portions of the first conductive blind via and the second conductive blind via respectively comprise a body region and a peripheral region, the body region corresponds to the head portion, the peripheral region surrounds at least part of the body region, and the peripheral contact portion is formed by extending the peripheral region.

10. The multilayer interposer with high bonding strength according to claim 9, wherein the peripheral region entirely surrounds the body region.

11. The multilayer interposer with high bonding strength according to claim 7, an electrical connection pad is configured on the most outer thin-film layer structure.

12. The multilayer interposer with high bonding strength according to claim 11, a plurality of wafer test points extending from the electrical connection pads are arranged in an matrix or in a wraparound way.

13. The multilayer interposer with high bonding strength according to claim 12, a conductive bump is configured on each electrical connection pad among the matrix arranged by the electrical connection pads.

14. The multilayer interposer with high bonding strength according to claim 7, the first conductive blind via is unaligned with the second conductive blind via by a predetermined distance.
